(19) United States
(12) Patent Application Publication
(10) Pub. No.: US 2016/0041463 A1
(43) Pub. Date: Feb. 11, 2016

(54) GLASS SUBSTRATE FOR OPTICAL LITHOGRAPHY

(71) Applicant: Asahi Glass Company, Limited, Chiyoda-ku (JP)

(72) Inventors: Yoshiaki Ikuta, Tokyo (JP); Masaaki Takata, Tokyo (JP)

(73) Assignee: Asahi Glass Company, Limited, Chiyoda-ku (JP)

(21) Appl. No.: 14/818,482

(22) Filed: Aug. 5, 2015

(30) Foreign Application Priority Data
Aug. 6, 2014 (JP) 2014-160202
Aug. 3, 2015 (JP) 2015-153162

(51) Int. Cl. G03F 1/50

(52) U.S. Cl. CPC G03F 1/50

(57) ABSTRACT

The present invention relates to a glass substrate for optical lithography containing a fluorine-containing synthetic quartz glass, in which the glass substrate has a pattern forming region, and when the pattern forming region is divided into a plural parts each having a strip shape along a long side direction of the pattern forming region such that the number of divisions is greater than or equal to 3, each part has an average fluorine concentration of greater than or equal to 1 mass % and a distribution of the average fluorine concentration among the parts is less than or equal to 0.45 mass %.

### TECHNICAL FIELD

The present invention relates to a glass substrate for optical lithography which is used as a photomask substrate for optical lithography.

### BACKGROUND ART

In optical lithography technology, a light exposure device for manufacturing a semiconductor integrated circuit by transferring a fine circuit pattern onto a wafer has been widely used. According to high integration and high functionalization of the semiconductor integrated circuit, refinement of the circuit pattern is being made. For the light exposure device, it is required that a circuit pattern formed on a photomask, which is finer and smaller than in the past, is accurately transferred to a predetermined position on a wafer surface with a greater focal depth and higher resolution. For this reason, for the light exposure device, the wavelength of an exposure light source is being made shorter. As the exposure light source, an ArF excimer laser (wavelength of 193 nm) are recently used, proceeding from conventional g-ray (wavelength of 436 nm), i-ray (wavelength of 365 nm) or KrF excimer laser (wavelength of 248 nm).

A semiconductor integrated circuit is generally manufactured by repeatedly performing a series of processes including a lithography step, an etching step and a film forming step 20 times to 30 times in total, to thereby sequentially laminate various shaped circuit patterns. Here, in the lithography step that is repeatedly performed 20 times to 30 times, the shape or the density of the circuit pattern which is transferred to the wafer from the photomask is different for each lithography step. Therefore, in order to manufacture one type of semiconductor integrated circuit, 20 types to 30 types of photomasks having a different shape or different density of the circuit pattern are used. Further a ratio of an area with no shielding film in the exposure area (referred to as an aperture ratio) is considerably different for each type of photomask by 2% to 80%. In the case of a photomask having a low aperture ratio, most of the light incident on the photomask is absorbed by the shielding film. Most of optical energy absorbed by the shielding film changes into heat, resulting in the increase of the temperature of the photomask. When the temperature of the photomask increases, a material constituting the photomask substrate thermally expands. As a result thereof, a position for forming the circuit pattern is shifted from a desired position, and thus the semiconductor integrated circuit obtained may generate an operation error.

As a material constituting the photomask substrate, synthetic quartz glass is mainly used for various reasons, for example, because the thermal expansion coefficient (CTE) in the vicinity of room temperature is small as approximately 500 ppb/K as compared to other optical materials such as calcium fluoride, light transmittivity is high in a wide range of wavelength from ultraviolet light to a visual light range, and chemical resistance is excellent. When the synthetic quartz glass is used as the material constituting a photomask substrate, in the semiconductor integrated circuit having a comparatively large circuit pattern dimension of greater than or equal to 50 nm, the request value for circuit pattern overlay accuracy is comparatively large as, for example, 10 nm. Therefore, in such a case, even when the circuit pattern is transferred by using a photomask having a small aperture ratio, the degradation of the circuit pattern overlay accuracy described above falls within an allowable range, and thus there has been no problem. However, when the circuit pattern dimension of the semiconductor integrated circuit is less than 50 nm, the request value for the circuit pattern overlay accuracy is small as, for example, less than 10 nm. Therefore, in such a case, there has been a problem that the degradation of the circuit pattern overlay accuracy described above due to the thermal expansion of the material constituting the photomask substrate is on the same level with an allowable value or exceeds the allowable value. In particular, when the photomask having a small aperture ratio and a positive resist having low sensitivity are used or when a photomask having a large aperture ratio and a negative resist having low sensitivity are used, the problem becomes remarkable. Specifically, when a photomask having an aperture ratio of less than or equal to 25% and a positive resist having a low sensitivity which requires a light exposure amount of greater than or equal to 30 mJ/cm² are used or when a photomask having an aperture ratio of greater than or equal to 75% and a negative resist having low sensitivity which requires a light exposure amount of greater than or equal to 30 mJ/cm² are used, the problem becomes remarkable. In addition, when the circuit pattern dimension of the semiconductor integrated circuit is small as, for example, less than 50 nm, the circuit pattern resolution of the light exposure device is not sufficient, and thus it is necessary that the circuit pattern of each layer constituting the semiconductor integrated circuit is divided into a plurality of circuit patterns and the circuit patterns are formed by performing light exposure plural times. In this case, requested pattern overlay accuracy is stricter as compared to a case where all circuit patterns of the respective layers are transferred by performing light exposure once, and the problem becomes more serious (refer to Non-Patent Documents 1, 2, 3, and 4, and Patent Document 1).

Patent Document 1: JP-A-2000-321753

Non-Patent Document 1: Effects of chrome pattern characteristics on image placement due to thermomechanical distortion of optical reticles during exposure, A. Abdo et. al., Journal of Vacuum Science & Technology B21, 3052 (2003)

Non-Patent Document 2: INTERNATIONAL TECHNOLOGY ROADMAP FOR SEMICONDUCTORS (revised every 2 or 3 years, for example, 2006 Edition)

Non-Patent Document 3: Investigation on reticle heating effect induced overlay error, Mi Jung Lim, et. al., SPIE, 9050-38 (2014)

Non-Patent Document 4: Imaging control functions of optical scanners, Hisashi Nishinaga, et. al., SPIE, 9052-10 (2014)

### SUMMARY OF THE INVENTION

As the photomask substrate for optical lithography, a photomask substrate formed in the shape of a rectangular parallelepiped of 152 mm×152 mm×6.35 mm is generally used. A region for forming an original circuit pattern in the photomask substrate (hereinafter, referred to as a “pattern forming region”) is a region formed in the shape of a rectangle of 132 mm×104 mm in the center of a major surface of 152 mm square of the substrate. The optical lithography has been changed from step and repeat type optical lithography in which the entire pattern forming region is irradiated with exposure light and the circuit patterns are collectively transferred to scan type optical lithography in which the photomask and the wafer are concurrently moved in parallel while the photomask is irradiated with narrow slit-like exposure light having a width of 2 mm to 3 mm and a length of approximately 104 mm, and the scan type optical lithography is mainly used for the reason because the size of a projection optical system of the light exposure device is able to be reduced, an influence of the surface shape of the wafer such as flatness on the circuit pattern transfer accuracy is comparatively easily corrected, and the like. In the scan type optical lithography, since the size of an illumination optical system lens or a projection optical system lens of the light exposure device is able to be reduced, a direction orthogonal to a movement direction of the photomask and the wafer is arranged to be a long side of a slit-like exposure area. Here, the movement direction of the photomask (a scanning direction) is generally coincident with a long side direction of the pattern forming region of the photomask.

A deformation amount ΔL of the photomask due to the thermal expansion has a relationship denoted by the following equation (A) when the thermal expansion coefficient of the material constituting the photomask substrate is “a”, the length of a portion to be a target (e.g., the length of the long side of the pattern forming region) is “L”, and a temperature variation is “ΔT”.

ΔL=α·L·ΔT (A)

As shown in the above equation (A), ΔL increases in the proportion of L. For this reason, the deformation amount due to the thermal expansion of the pattern forming area of the photomask substrate becomes its maximum at the diagonal direction of the pattern forming area in which L is maximized, that is, the deformation amount due to the thermal expansion per a length of 168 mm is the maximum. However, as for the modification due to the thermal expansion in a direction of the short side of 104 mm in the pattern forming area, when the slender rectangular exposure light scans the photomask, it is possible to perform correction such as continuous adjustment of a magnification ratio for reductively projecting the circuit pattern on the photomask to the wafer. For this reason, the degradation of the circuit pattern overlay accuracy due to the thermal expansion in the direction of the short side of 104 mm in the pattern forming area does not cause a major problem. On the other hand, it is difficult to perform such a correction described above for the modification due to the thermal expansion in the direction of the long side of 132 mm in the pattern forming area. For this reason, a problem in the modification due to the thermal expansion of the pattern forming area of the photomask substrate is the thermal expansion in the long side direction of the pattern forming region which is not easily corrected. In this case, it is preferable to decrease the amount of thermal expansion per a length of 132 mm in the long side direction of the pattern forming area in which L is maximized.

In order to solve the above-described problems of the conventional technology, an object of the present invention is to provide a glass substrate for optical lithography in which thermal expansion due to light exposure and degradation in pattern accuracy due to the thermal expansion are suppressed.

To achieve the above-described object, the present invention provides a glass substrate for optical lithography containing a fluorine-containing synthetic quartz glass,

in which the glass substrate has a pattern forming region, and

when the pattern forming region is divided into a plural parts each having a strip shape along a long side direction of the pattern forming region such that the number of divisions is greater than or equal to 3, each part has an average fluorine concentration of greater than or equal to 1 mass % and a distribution of the average fluorine concentration among the parts is less than or equal to 0.45 mass %.

The glass substrate for optical lithography of the present invention preferably has a fluorine concentration distribution being less than or equal to 0.82 mass % in the pattern forming region.

In the glass substrate for optical lithography of the present invention, especially in the glass substrate for ArF lithography using the light source having a wavelength of 193 nm, it is preferred that the glass substrate has an absorption coefficient k₁₆₃ (1/cm) at a wavelength of 163 nm in the pattern forming region, satisfying the following equation (1):

$${k}_{163} ( 1 / cm ) ≦ a ln [ \frac{1}{1 - Δ T} ] \qquad ( 1 )$$

in the equation (1), a is 9.74×10⁴, and ΔT is denoted by the following equation

$$Δ T = \frac{2 {bW}_{F} ( - 1 + {n}_{0} ( {n}_{0} - {bW}_{F} ) )}{( 1 + {n}_{0}^{2} ) ( 1 + {( {n}_{0} - {bW}_{F} )}^{2} )} \qquad ( 2 )$$

in the equation (2), n₀ is 1.561, b is 5.04×10⁻³, and W_{F} is a fluorine concentration (mass %) in the pattern forming region.

In the glass substrate for optical lithography of the present invention, each part preferably has an average fictive temperature being higher than or equal to 1,000° C.

In the present invention, it is possible to provide a glass substrate for optical lithography in which thermal expansion due to light exposure and degradation in pattern accuracy caused by the thermal expansion due to the light exposure are suppressed.

### BRIEF DESCRIPTION OF THE DRAWINGS

FIG. 1 is a plan view of a photomask substrate for optical lithography.

### DETAILED DESCRIPTION OF THE INVENTION

Hereinafter, the present invention will be described.

The glass substrate for optical lithography of the present invention contains a synthetic quartz glass containing fluorine as a constituent material. By adjusting the fluorine concentration of a pattern forming region so as to satisfy the following conditions, excellent properties as a glass substrate for optical lithography can be achieved such that the amount of thermal expansion of the pattern forming region and a variation in the amount of thermal expansion in the pattern forming region at the time of performing optical lithography are small. Further, by adjusting the fluorine concentration of a pattern forming region so as to satisfy the following conditions, excellent properties as a glass substrate for optical lithography can be achieved such that the light ray transmittance at a wavelength of the light source light, that is, wavelength of 193 nm, 248 nm or 365 nm in the pattern forming region is high and a variation in the light ray transmittance at the wavelength in the pattern forming region is low. The glass substrate for optical lithography of the present invention is suitable as a photomask substrate for optical lithography.

As described above, as the photomask substrate for optical lithography is used generally a substrate formed in a shape of rectangular parallelepiped of 152 mm×152 mm×6.35 mm. The pattern forming region is a region formed in the shape of a rectangle of 132 mm×104 mm in the center of a major surface of the substrate of 152 mm square.

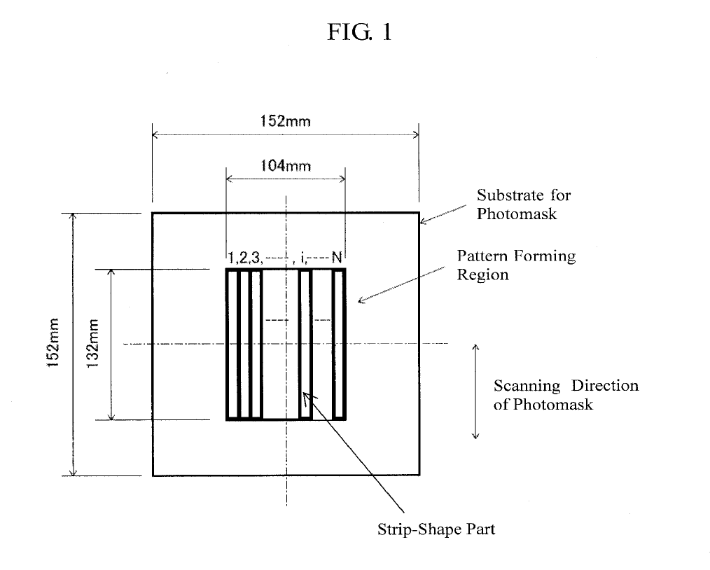

FIG. 1 is a plan view of the photomask substrate for optical lithography. The photomask substrate illustrated in FIG. 1 has a major surface of 152 mm square, and the region of 132 mm×104 mm in the center of the major surface is the pattern forming region. The scanning direction of the photomask substrate at the time of performing optical lithography is coincident with a long side direction of the pattern forming region.

In the glass substrate for optical lithography of the present invention, when the pattern forming region is divided into a plural parts each having a strip shape along the long side direction of the pattern forming region such that the number of divisions is greater than or equal to 3, an average fluorine concentration in each strip part and a distribution of the average fluorine concentration among the strip parts satisfy the following conditions. FIG. 1 illustrates an image of a case where the pattern forming region of the photomask substrate is divided into a plural parts of a strip shape along the long side direction such that the number of divisions is N.

In the glass substrate for optical lithography of the present invention, the reason for evaluating the average fluorine concentration in each strip part and the distribution of the average fluorine concentration among the strip parts by dividing the pattern forming region into a plural parts each having a strip shape along the long side direction of the pattern forming region is as follows.

As described above, the degree of degradation in circuit pattern overlay accuracy due to the thermal expansion amount in the pattern forming region is different between in the scanning direction of the photomask and in the direction perpendicular to the scanning direction. The degradation of the overlay accuracy in the scanning direction of the photomask is large and therefore is a major problem. As described above, the deformation amount AL due to the thermal expansion of the photomask can be obtained from a product of a thermal expansion coefficient α of the material constituting the photomask substrate, a length L of a portion to be a target and a temperature variation ΔT. When synthetic quartz glass containing fluorine is used as the constituent material of the glass substrate for optical lithography of the present invention, the fluorine concentration affects the thermal expansion coefficient. The thermal expansion coefficient decreases as the fluorine concentration becomes higher. For this reason, by controlling the average fluorine concentration in each strip part along the long side direction of the pattern forming region which is the scanning direction of the photomask, it is possible to control the amount of thermal expansion in the scanning direction of the photomask. In addition, by controlling the distribution of the average fluorine concentration among the strip parts, it is possible to control the distribution of the amount of thermal expansion in the pattern forming region.

In the glass substrate for optical lithography of the present invention, the reason for dividing the pattern forming region such that the number of divisions is greater than or equal to 3 is as follows. That is, it is necessary that the amount of thermal expansion of the glass substrate in the pattern forming region is suppressed to be less than or equal to a predetermined value and it is also necessary that the distribution of the amount of thermal expansion of the glass substrate in the pattern forming region is suppressed to be less than or equal to another predetermined value. For these reasons, it is necessary to set the number of divisions to greater than or equal to 3 to thereby define the distribution of the amount of thermal expansion among the divided regions.

In the glass substrate for optical lithography of the present invention, the number of divisions of the pattern forming region is preferably greater than or equal to 5, is more preferably greater than or equal to 7, and even more preferably greater than or equal to 10.

In the glass substrate for optical lithography of the present invention, the average fluorine concentration in each strip part defined as described above is greater than or equal to 1 mass %. When the average fluorine concentration in each strip part is greater than or equal to 1 mass %, it is preferable because the amount of thermal expansion in the long side direction due to an increase of 0.1° C. in a temperature region of from 20° C. to 27° C. in each strip part is sufficiently small as, for example, less than or equal to 5 nm.

In order to prevent a dimension change in the photomask substrate due to a temperature change at the time of performing optical lithography, the temperature of the photomask substrate is controlled in a temperature range of 20° C. to 27° C. However, the temperature of the photomask substrate slightly increases due to light absorption at the time of performing light exposure. The amount of rise in temperature depends on various conditions such as an aperture ratio of the photomask, a light exposure amount, the number of times of light exposure per unit time, and the like, and the temperature may increase by 0.1° C. to 2° C. When the amount of thermal expansion of the glass substrate due to an increase of 0.1° C. in the temperature region of from 20° C. to 27° C. is approximately less than or equal to 5 nm, the amount of thermal expansion of the photomask at the time of performing the light exposure is sufficiently small, and thus the degradation of the pattern accuracy due to the thermal expansion at the time of performing the light exposure is further suppressed.

In the glass substrate for optical lithography of the present invention, the average fluorine concentration in each strip part defined as described above is preferably greater than or equal to 1.5 mass %, is more preferably greater than 2 mass %, and is even more preferably greater than or equal to 2.5 mass %.

In the present invention, a method of obtaining the average fluorine concentration in each strip part and the fluorine concentration distribution in the pattern forming region described below includes the following methods for example.

First, direct measurement of the fluorine concentration is performed with respect to one arbitrary portion of the major surface in the glass substrate for optical lithography by a method described below. Subsequently, a refractive index distribution of the major surface in the glass substrate for optical lithography including the portion in which the fluorine concentration is measured, that is, a difference Δn(i) in a refractive index between each point (i) of the major surface in the glass substrate for optical lithography and the portion in which the fluorine concentration is measured is measured by using laser interferometer (e.g., Verifire and Mark IV manufactured by Zygo Corporation, G310S manufactured by Fujinon Corporation, FlatMaster manufactured by Tropel Corporation, and the like). By using the fluorine concentration and refractive index difference thus obtained, the average fluorine concentration and the fluorine concentration distribution are able to be obtained according to the following equations (3) and (4).

$$\begin{matrix}AverageFluorineConcentration = {C}_{{F}_{0}} + \frac{1}{p} \frac{1}{N} {\sum }_{i = 1}^{N} Δ n ( i ) & ( 3 ) \\ Fluorine Concentration Distribution = ( Δ {n ( i )}_{max} - Δ {n ( i )}_{min} ) / p & ( 4 )\end{matrix}$$

In the equations (3) and (4), “p” is fluorine concentration dependency of the refractive index in the major surface of the glass substrate for optical lithography. “p” depends on a wavelength, and for example, when the wavelength is 633 nm, “p” is 3.68×10⁻⁷ (1/wt-ppm). C_{F0} is a fluorine concentration (mass %) which is measured at one arbitrary portion in the major surface of the glass substrate for optical lithography.

The average fluorine concentration in each strip part is calculated by the above-described equation (3) relevant to the average fluorine concentration, by using the difference Δn(i) in the refractive index between each of the points (i) in the respective strip part and the portion in which the fluorine concentration is measured.

The fluorine concentration distribution in the pattern forming region is calculated by the above-described equation (4) relevant to the fluorine concentration distribution, by using the difference Δn(i) in the refractive index between each of the points (i) in the pattern forming region and the portion in which the fluorine concentration is measured.

The direct measurement method of fluorine concentration is as follows. That is, in accordance with the method disclosed in the Chemical Society of Japan, 1972(2), 350, a glass is heated and melted by anhydrous sodium carbonate, and thereto are added distilled water and hydrochloric acid (1+1), to thereby prepare a sample solution. An electromotive force of the sample solution is measured by a radiometer using No.945-220 and No.945-468 manufactured by Radiometer Corporation as a fluorine ion selective electrode and a comparison electrode, respectively. The fluorine concentration is able to be obtained on the basis of a calibration curve prepared in advance by using a fluorine ion standard solution.

Alternatively, the average fluorine concentration in each strip part, the distribution of the average fluorine concentration among the strip parts and the fluorine concentration distribution in the pattern forming region are able to be obtained by a Raman scattering spectroscopic analysis method. First, at least one standard sample having a known and sufficiently homogeneous fluorine concentration is determined in advance. The Raman scattering intensities at the wave numbers of 800 cm ⁻¹ and 935 cm⁻¹ in the standard sample are measured as I_{800,s} and I_{935,s}, respectively, and a ratio I_{935,s}/I_{800,s} thereof is obtained. A value y=C_{F,s}/(I_{935,s}/I_{800,s}) obtained by dividing the known fluorine concentration C_{F,s} of the standard sample with the ratio is calculated as a calibration coefficient y. It is preferable that the Raman scattering intensity ratio I_{935,s}/I_{800,s} is periodically measured at a predetermined frequency and is updated. The known fluorine concentration C_{F,s} is able to be obtained by the direct measurement method of the fluorine concentration described above.

Next, the Raman scattering intensity ratio (I_{935,i}/I_{800,i}) of each of the points (i) in the pattern forming region in the measurement target substrate is measured. The calibration coefficient y is set to the Raman scattering intensity ratio of each of the points (i), and the fluorine concentration C_{F,i} of each of the points (i) is calculated by using the following equation (5). It is preferable that the calibration coefficient y is used a suitably updated value.

C_{F,i}=y×(I_{935,i}/I_{800,i}) (5)

The average fluorine concentration in the strip part is able to be calculated by the following equation (6) using the fluorine concentration of each of the points (i) in the focused strip part among the fluorine concentration C_{F,i} of each of the points (i) in the pattern forming region obtained by expression (5). In the equation (6), N indicates the number of fluorine concentration measurement points in the focused strip.

$$Average Fluorine Concentration in Strip = \frac{1}{N} {\sum }_{In Strip}^{N} {C}_{F , i} \qquad ( 6 )$$

The distribution of the average fluorine concentration between the strip parts is defined by a difference between the maximum value and the minimum value in points (i) in the target strip part. In addition, the fluorine concentration distribution in the pattern forming region is defined by a difference between the maximum value and the minimum value in the points (i) in the pattern forming region.

Also by using equation (5) described above, the average fluorine concentration in the respective strip and the fluorine concentration distribution in the pattern forming region are able to be obtained.

In addition, in the synthetic quartz glass constituting the glass substrate for optical lithography, a fictive temperature of the synthetic quartz glass may affect the thermal expansion coefficient. The thermal expansion coefficient may decrease as the fictive temperature becomes higher. For this reason, similar to the fluorine concentration described above, when the average fictive temperature in each strip part is controlled, the amount of thermal expansion is able to be further controlled, and which is preferable.

In the present invention, the average fictive temperature in each strip part is able to be obtained by the following manner. First, each strip part is divided into a plurality of small pieces of greater than or equal to two, and the fictive temperature in each of the small pieces is measured by, for example, using a method disclosed in WO 2011/052610. The average fictive temperature in the strip part is able to be obtained by the arithmetic mean of the fictive temperature measurement points in the focused strip part. In this case, when the fictive temperature is measured in accordance with WO 2011/052610, it is necessary to add the following operations to the method disclosed in the document. That is, as a sample used at the time of obtaining the calibration curve, a plurality of fluorine-containing samples having a fluorine concentration which is regarded to be the same with each other is prepared. These samples are held at a respective different holding temperature for a sufficient long period of time, and then they are rapidly cooled. After the cooling, an infrared ray absorption spectrum of these samples is measured in accordance with the disclosure of WO 2011/052610. Further, the measurement is performed in the same procedure by using samples in which the fluorine concentration is changed. The measurement may be performed by preparing at least two fluorine concentrations of the sample, or by preferably preparing four fluorine concentrations of the sample. Data obtained by the procedure described above is used as the calibration curve by taking the holding temperature and the fluorine concentration as two explanatory variables and by obtaining a regression formula in which an infrared ray absorption spectrum peak wave number in the vicinity of approximately 2260 cm⁻¹ is used as an objective variable.

In the glass substrate for optical lithography of the present invention, the thermal expansion coefficient decreases as the average fictive temperature in the strip becomes higher, and which is preferable. In the glass substrate for optical lithography of the present invention, the average fictive temperature in each strip part defined as described above is preferably higher than or equal to 1,000° C., more preferably higher than or equal to 1,050° C., and even more preferably higher than or equal to 1,100° C.

As a relationship between fluorine content and thermal expansion coefficient of the synthetic quartz glass containing fluorine, in FIG. 7 of U.S. Pat. No. 6,242,136, a relationship between the fluorine content and an average thermal expansion coefficient in a temperature region of from room temperature to 300° C. is shown. In addition, in FIG. 1 of the 12^{th} European Conference on Optical Communication, Technical Digest Volume 1 Page 3-6 (Characteristics of Fluorine-doped silica glass, H. Takahashi, A. Oyobe, and R. Setaka, Central Research Laboratory, Furukawa Electric Company Ltd.), a relationship between the fluorine content and the average thermal expansion coefficient in the temperature region from room temperature to 400° C. is shown. However, in these disclosures, a relationship between the average thermal expansion coefficient in a comparatively wide temperature region of from room temperature to 300° C. and the fluorine content is just shown, but the thermal expansion coefficient in a narrow temperature range of from 20° C. to 27° C. in which the optical lithography is actually performed is not shown. In addition, the optical glass for ultraviolet light disclosed in JP-A-H08-67530 is formed of a synthetic quartz glass containing fluorine of greater than or equal to 1 mass %. However, an effect of containing fluorine in the glass is for improving laser resistance, but the relationship between the fluorine concentration and the thermal expansion coefficient is not shown.

In the glass substrate for optical lithography of the present invention, the distribution of the average fluorine concentration among the strip parts defined as described above is less than or equal to 0.45 mass %. The distribution of the average fluorine concentration among the strip parts is a difference between the maximum value and the minimum value of the average fluorine concentration in a strip part among the entirety of the strip parts constituting the pattern forming region.

When the distribution of the average fluorine concentration among the strip parts is less than or equal to 0.45 mass %, the distribution of the amount of thermal expansion due to an increase of 0.1° C. in the temperature region of from 20° C. to 27° C. among the strip parts is sufficiently small.

When the distribution of the amount of thermal expansion due to an increase of 0.1° C. in the temperature region of from 20° C. to 27° C. is a sufficiently small value, since the distribution of the amount of thermal expansion is sufficiently small at the time of performing light exposure, the degradation of the pattern accuracy due to the thermal expansion at the time of performing the light exposure is further suppressed.

In the glass substrate for optical lithography of the present invention, the distribution of the average fluorine concentration among the strip parts is more preferably less than or equal to 0.4 mass % and even more preferably less than or equal to 0.35 mass %.

As described above, in the glass substrate for optical lithography of the present invention, it is possible to sufficiently decrease the distribution of the amount of thermal expansion of the glass substrate due to a temperature increase in the photomask assumed at the time of performing light exposure. For this reason, accuracy degradation of the pattern which is transferred to a resist on a wafer due to the thermal expansion of the glass substrate at the time of performing the light exposure is suppressed.

One of the reasons that a synthetic quartz glass containing fluorine is used as the constituent material of the glass substrate for optical lithography of the present invention is because light ray transmittance at wavelength of 193 nm, 248 nm and 365 nm is improved by using the synthetic quartz glass containing fluorine. The reason that the transmittance at these wavelength increases by using the synthetic quartz glass containing fluorine is because the refractive index of the synthetic quartz glass decreases when it contains fluorine, and a surface reflection ratio decreases.

However, when a variation in the fluorine concentration in the pattern forming region increases, an in-plane variation in the pattern dimension at the time of performing light exposure is degraded, and which causes a problem.

In the glass substrate for optical lithography of the present invention, it is preferable that the fluorine concentration distribution in the pattern forming region is less than or equal to 0.82 mass %.

When the fluorine concentration distribution in the pattern forming region is less than or equal to 0.82 mass %, a transmittance distribution at a wavelength of 193 nm in the pattern forming region is sufficiently small as, for example, less than or equal to 0.1%. Accordingly, the degradation of the pattern dimension accuracy at the time of performing light exposure is further suppressed. In addition, light intensity which transmits through the photomask and projected to the wafer at the time of performing the light exposure is homogenized, and the in-plane variation in the pattern dimension decreases.

In the glass substrate for optical lithography of the present invention, the fluorine concentration distribution in the pattern forming region is more preferably less than or equal to 0.7 mass %, and even more preferably less than or equal to 0.6 mass %.

As for the homogeneousness of the refractive index distribution in the synthetic quartz glass containing fluorine, Japanese Patent No. 3,654,500 discloses that a difference (Δn) between the maximum value and the minimum value of the refractive index of a quartz glass material for F₂ excimer laser optical member is 2×10⁻⁵. However, the refractive index distribution is not the refractive index distribution at a wavelength of 193 nm but a value at a wavelength of 157 nm, and thus there is no relationship with respect to the transmittance distribution at a wavelength of 193 nm.

In addition, by using the synthetic quartz glass containing fluorine as the constituent material of the glass substrate for optical lithography, the refractive index of the glass substrate for optical lithography decreases and as a result, the surface reflection ratio thereof also decreases, and therefore, the transmittance at a wavelength of 193 nm increases. However, in general, when a synthetic quartz glass contains fluorine, an oxygen deficiency defect may occur in the synthetic quartz glass. The oxygen deficiency defect has a light absorption band centered at a wavelength of 163 nm, and thus when the oxygen deficiency defect occurs, the transmittance at a wavelength 193 nm may also decrease. In this case, however, since a wavelength of 248 nm or 365 nm of the light source light of KrF lithography or i-ray lithography is considerably away from the central wavelength of 163 nm of the absorption band of the oxygen deficiency defect, the transmittance may not decrease. Therefore, in the glass substrate for optical lithography of the present invention, in the case of a glass substrate for ArF lithography in which the wavelength of the light source light of the lithography is 193 nm, as an absorption coefficient k₁₆₃ (1/cm) at a wavelength of 163 nm in the pattern forming region satisfies a predetermined condition, it is possible to lower the transmittance decrease amount at a wavelength of 193 nm due to the occurrence of the light absorption band due to the oxygen deficiency defect centered at a wavelength of 163 nm as compared to a transmittance increase amount at a wavelength of 193 nm due to fluorine contained therein. As a result thereof, even when fluorine is contained, the transmittance at a wavelength of 193 nm may not decrease. This will be specifically described as follows.

When the glass substrate for optical lithography of the present invention is used as a glass substrate for ArF lithography, it is preferable that the absorption coefficient k₁₆₃ (1/cm) at a wavelength of 163 nm in the pattern forming region satisfies a relationship of the following equation (1).

$${k}_{163} ( 1 / cm ) ≦ a ln [ \frac{1}{1 - Δ T} ] \qquad ( 1 )$$

In the equation (1), ΔT is denoted by the following equation (2).

$$Δ T = \frac{2 {bW}_{F} ( - 1 + {n}_{0} ( {n}_{0} - {bW}_{F} ) )}{( 1 + {n}_{0}^{2} ) ( 1 + {( {n}_{0} - {bW}_{F} )}^{2} )} \qquad ( 2 )$$

In the equations (1) and (2), a is 9.74×10⁴, b is 5.04×10⁻³, n₀ is 1.561, and W_{F} is the fluorine concentration (mass %) in the pattern forming region.

When the absorption coefficient k₁₆₃ at a wavelength of 163 nm in the pattern forming region satisfies a relationship of the equation (1) described above, the transmittance decrease amount at a wavelength 193 nm due to the occurrence of the light absorption band centered at a wavelength of 163 nm falls below the transmittance increase amount at a wavelength of 193 nm due to fluorine added to the pattern forming region. For this reason, the transmittance at a wavelength of 193 nm may not decrease due to the occurrence of the light absorption band centered at a wavelength of 163 nm. In the glass substrate for optical lithography of the present invention, especially in the glass substrate for ArF lithography, the transmittance at a wavelength of 193 nm is preferably greater than or equal to 90.75%, and more preferably greater than or equal to 90.8%.

As described above, in the case where the absorption coefficient k₁₆₃ at a wavelength of 163 nm in the pattern forming region satisfies the relationship of the equation (1) described above, it is possible to slightly increase the transmittance at a wavelength of 193 nm as compared to a known glass substrate for optical lithography in which fluorine is not contained. For this reason, a light exposure amount necessary for exposing the resist on a wafer also slightly decreases, and thus it is possible to slightly suppress a temperature increase at the time of performing the light exposure.

### EXAMPLES

Hereinafter, the present invention will be further described in detail with reference to examples, but the present invention is not limited thereto. Furthermore, Examples 1, 2, 4, and 13 are comparative examples, and Examples 3, 5 to 12, and 14 to 18 are inventive examples.

The synthetic quartz glass substrates having different fluorine concentrations are prepared and the following evaluations are performed thereon. The results are shown in the following tables. The synthetic quartz glass substrate is formed in the shape of a rectangular parallelepiped of 152 mm×152 mm×6.35 mm, and a region of 132 mm×104 mm in the center of one major surface of 152 mm square is taken as a pattern forming region. The pattern forming region is divided into a plural parts each having a strip shape along the long side direction of the pattern forming region such that the number of divisions is ten (10) (refer to FIG. 1).

According to the method described above, regarding the case where the pattern forming region is divided into ten parts in the shape of a strip, the average fluorine concentration and average fictive temperature in each strip part, and the fluorine concentration distribution in the pattern forming region are obtained.

In addition, the distribution of the average fluorine concentration among the strip parts is obtained as a difference between the maximum value and the minimum value of the average fluorine concentration in the strip part among the entire strip parts constituting the pattern forming region. Here, the refractive index distribution in a pattern forming area of 132 mm×104 mm is measured at a pitch of 0.66 mm by using a Fizeau interferometer G310S manufactured by Fujinon Corporation (light source wavelength of 633 nm).

In the table, the average fluorine concentration in the strip part indicates the minimum value of the average fluorine concentration in the divided ten strip parts. When the value is greater than or equal to 1 mass %, it is indicated that the average fluorine concentration in each strip part is greater than or equal to 1 mass %. Similarly, in the table, the average fictive temperature in the strip part indicates the minimum value of the average fictive temperature in the divided ten strip parts. When the value is higher than or equal to 1,000° C., it is indicated that the average fictive temperature in each strip part is higher than or equal to 1,000° C.

The average thermal expansion coefficient in each strip part is obtained in the following manner because a sample size of a thermal expansion meter to be used is approximately 15 mm which is smaller than that of the present glass substrate.

Step 1) The thermal expansion coefficient of a plurality of types of fluorine-containing synthetic quartz glass having different fluorine concentration is measured in a range of −150° C. to +200° C. by using a thermal expansion meter (a quadrupole optical path Michelson light interferometer type thermal expansion meter LIX2 manufactured by Advance Rico, Inc.). The measurement accuracy of the thermal expansion coefficient by this method is approximately 20 ppb/° C.

Step 2) The fluorine concentration dependency of the thermal expansion coefficient of the fluorine-containing synthetic quartz glass at a temperature of 25° C. is obtained.

Step 3) The average thermal expansion coefficient in each strip part at a temperature of 25° C. is obtained from the average fluorine concentration in the respective strip parts obtained by the procedure described above and the fluorine concentration dependency of the thermal expansion coefficient obtained in Step 2).

In the table, the average thermal expansion coefficient in the strip part indicates the maximum value of the average thermal expansion coefficient in the divided ten strip parts.

The amount of thermal expansion due to an increase of 0.1° C. in the temperature region of from 20° C. to 27° C. in each strip part is obtained by using the average thermal expansion coefficient in the respective strip part at a temperature of 25° C. which is obtained by the procedure described above. The distribution of the amount of thermal expansion due to an increase of 0.1° C. in the temperature region of from 20° C. to 27° C. among the strip parts is obtained as a difference between the maximum value of the amount of thermal expansion in a strip part and the minimum value of the amount of thermal expansion in a strip part among the strip parts.

Two fluorine-containing synthetic quartz glass substrates formed in the shape of a rectangular parallelepiped of 152 mm×152 mm×6.4 mm are prepared and the respective two facing surfaces of 152 mm×152 mm including the pattern forming region of 132 mm×104 mm is mirror-polished by a known method so that the surface roughness thereof is less than or equal to 0.1 nm (as an RMS value in an area of 1 μm×1 μm), thereby preparing one fluorine-containing synthetic quartz glass substrate having the shape of a rectangular parallelepiped having an outer shape of 152 mm×152 mm×6.35 mm and one synthetic quartz glass substrate having the shape of a rectangular parallelepiped of 152 mm×152 mm×2.8 mm. In the thus obtained two types of synthetic quartz glass substrates having different thicknesses, the transmittance at a wavelength of 163 nm in the pattern forming region of 132 mm×104 mm is measured at total 42 points in a lattice pattern at intervals of 20 mm by using a vacuum ultraviolet spectrophotometer (a vacuum ultraviolet spectrophotometer system manufactured by Bunkoukeiki Co., Ltd.). According to the following equation (7), in each of the measurement points, the absorption coefficient k₁₆₃ at a wavelength of 163 nm is obtained from the respective transmittances T_{1, 6.35} mm and T_{1, 2.8 mm} at a wavelength of 163 nm at thicknesses of 6.35 mm and 2.8 mm of the respective samples.

k₁₆₃(1/cm)=ln(T_{1, 2.8 mm}/T_{1, 6.35 mm})/(0.635−0.28) (7)

Here, when T_{1, 2.8 mm} is less than or equal to 0.1% of a measurement limit value of the transmittance, the transmittances T_{2, 6.35 mm} and T_{2, 2.8 mm} at a wavelength of 180 nm are measured by the same manner as that described above, and according to the following equation (8), the absorption coefficient k₁₆₃ at a wavelength of 163 nm is indirectly obtained.

k₁₆₃(1/cm)=C₁₆₃₋₁₈₀×ln(T_{2, 2.8 mm}/T_{2, 6.35 mm})/(0.635−0.28) (8)

Here, C₁₆₃₋₁₈₀ indicates a ratio of the absorption coefficients at a wavelength of 163 nm and a wavelength of 180 nm in the light absorption band due to the oxygen deficiency defect, and the value thereof is 35.8.

In the table, the value (k₁₆₃ (in the pattern forming region, 1/cm) indicates the maximum value of the absorption coefficient at a wavelength of 163 nm among total 42 points. In addition, in the table, the value (k₁₆₃ (allowable upper limit, 1/cm)) indicates an allowable upper limit of k₁₆₃. When the value of k₁₆₃ (in the pattern forming region, 1/cm) is less than k₁₆₃ (allowable upper limit, 1/cm), the relationship of the equation (1) is satisfied.

One fluorine-containing synthetic quartz glass substrate formed in the shape of a rectangular parallelepiped of 152 mm×152 mm×6.4 mm is prepared and two facing surfaces of 152 mm×152 mm including the pattern forming region of 132 mm×104 mm is mirror-polished by a known method so that the surface roughness thereof is less than or equal to 0.1 nm (as an RMS value in an area of 1 μm×1 μm), thereby preparing a fluorine-containing synthetic quartz glass substrate having the shape of a rectangular parallelepiped having an outer shape of 152 mm×152 mm×6.35 mm is obtained. In the obtained fluorine-containing synthetic quartz glass substrate, the transmittance at a wavelength of 193 nm in the pattern forming region of 132 mm×104 mm is measured at total 154 points in a lattice pattern at intervals of 10 mm by using an ultraviolet spectrophotometer (manufactured by Hitachi High-Technologies Corporation, U4100). In the table, the transmittance at 193 nm (in the pattern forming region) is the minimum value of the measurement value among total 154 points, and in the table, the transmittance distribution at 193 nm (in the pattern forming region) is a difference between the maximum value and the minimum value of the measurement value among total 154 points.

TABLE 1

| | Average Fluorine | Distribution of Average | Fluorine Concentration | Average Fictive | Average Thermal | Amount of Thermal |
|---|---|---|---|---|---|---|
| | Concentration | Fluorine Concentration | Distribution in Pattern | Temperature in | Expansion Coefficient | Expansion in Each |
| | in Each Strip Part | among Strip Parts | Forming Region | Each Strip Part | in Each Strip Part | Strip Part |
| | (wt %) | (wt %) | (wt %) | (° C.) | (ppb/K) | (+0.1° C.) (nm) |
| Ex. 1 | 0.0 | 0.00 | 0.00 | 1,010 | 499 | 6.58 |
| Ex. 2 | 0.8 | 0.42 | 0.63 | 1,010 | 426 | 5.62 |
| Ex. 3 | 1.4 | 0.37 | 0.55 | 1,010 | 371 | 4.90 |
| Ex. 4 | 1.4 | 0.50 | 0.75 | 1,010 | 371 | 4.90 |
| Ex. 5 | 1.4 | 0.37 | 0.55 | 1,010 | 371 | 4.90 |
| Ex. 6 | 1.4 | 0.37 | 0.55 | 1,010 | 371 | 4.90 |
| Ex. 7 | 1.8 | 0.37 | 0.56 | 1,010 | 334 | 4.41 |
| Ex. 8 | 2.2 | 0.33 | 0.50 | 1,010 | 298 | 3.93 |
| Ex. 9 | 2.7 | 0.29 | 0.44 | 1,010 | 252 | 3.33 |
| Ex. 10 | 2.7 | 0.31 | 0.47 | 1,010 | 252 | 3.33 |
| Ex. 11 | 2.7 | 0.29 | 0.44 | 1,010 | 252 | 3.33 |
| Ex. 12 | 2.7 | 0.29 | 0.87 | 1,010 | 252 | 3.33 |
| Ex. 13 | 2.7 | 0.96 | 1.45 | 1,010 | 252 | 3.33 |
| Ex. 14 | 3.0 | 0.25 | 0.38 | 1,010 | 225 | 2.97 |
| Ex. 15 | 3.5 | 0.20 | 0.30 | 1,010 | 179 | 2.37 |
| Ex. 16 | 1.4 | 0.37 | 0.55 | 1,110 | 342 | 4.52 |
| Ex. 17 | 1.4 | 0.37 | 0.55 | 980 | 379 | 4.99 |
| Ex. 18 | 3.0 | 0.25 | 0.38 | 1,110 | 196 | 2.59 |

TABLE 2

| | Distribution | | | | Transmittance |
|---|---|---|---|---|---|
| | of Amount of | k₁₆₃ | k₁₆₃ | Transmittance | Distribution |
| | Thermal Expansion | (in Pattern | (Allowable | at 193 nm (in | at 193 nm (in |
| | among Strip Parts | Forming | Upper Limit, | Pattern Forming | Pattern Forming |
| | (+0.1° C.) (nm) | Region, l/cm) | l/cm) | Region, %) | Region, %) |
| Ex. 1 | 0.00 | 0.14 | n/r | 90.71 | 0.00 |
| Ex. 2 | 0.51 | <0.03 | 96 | 90.81 | 0.08 |
| Ex. 3 | 0.44 | <0.03 | 167 | 90.88 | 0.07 |
| Ex. 4 | 0.60 | <0.03 | 167 | 90.88 | 0.09 |
| Ex. 5 | 0.44 | 85 | 167 | 90.80 | 0.06 |
| Ex. 6 | 0.44 | 240 | 167 | 90.66 | 0.05 |
| Ex. 7 | 0.45 | <0.03 | 215 | 90.93 | 0.07 |
| Ex. 8 | 0.40 | <0.03 | 263 | 90.98 | 0.06 |
| Ex. 9 | 0.35 | <0.03 | 322 | 91.04 | 0.05 |
| Ex. 10 | 0.37 | <0.03 | 322 | 91.04 | 0.06 |
| Ex. 11 | 0.35 | 240 | 322 | 90.82 | 0.07 |
| Ex. 12 | 0.35 | <0.03 | 322 | 91.04 | 0.15 |
| Ex. 13 | 1.16 | 410 | 322 | 90.66 | 0.30 |
| Ex. 14 | 0.30 | <0.03 | 358 | 91.08 | 0.05 |
| Ex. 15 | 0.24 | <0.03 | 418 | 91.14 | 0.04 |
| Ex. 16 | 0.45 | <0.03 | 167 | 90.88 | 0.07 |
| Ex. 17 | 0.45 | <0.03 | 167 | 90.88 | 0.09 |
| Ex. 18 | 0.30 | <0.03 | 358 | 91.08 | 0.05 |

In inventive examples (Examples 3, 5 to 12, and 14 to 18), since the average fluorine concentration in each strip part is greater than or equal to 1 mass %, the amount of thermal expansion due to an increase of 0.1° C. in the temperature region of from 20° C. to 27° C. in each strip part is sufficiently small as less than or equal to 5 nm. In addition, since the distribution of the average fluorine concentration among strip parts is less than or equal to 0.45 mass %, the distribution of the amount of thermal expansion due to an increase of 0.1° C. in the temperature region of from 20° C. to 27° C. among strip parts is sufficiently small as less than or equal to 0.5 nm.

In both Examples 1 and 2, since the average fluorine concentration in each strip part is less than 1 mass %, the amount of thermal expansion due to an increase of 0.1° C. in the temperature region of from 20° C. to 27° C. in strip part is large as greater than 5 nm.

In both Examples 4 and 13, the distribution of the average fluorine concentration among strip parts is greater than 0.45 mass %, the distribution of the amount of thermal expansion due to an increase of 0.1° C. in the temperature region of from 20° C. to 27° C. among strip parts is large as greater than 0.5 nm.

The value of the distribution of the amount of thermal expansion in the Table 2 is a calculation value based on the supposition that a mechanical constraint force is not applied among strip parts and each of the strip parts is freely modified due to expansion and contraction. In practice, the mechanical constraint force is applied, and thus an actually-measured value of the distribution of the amount of the thermal expansion does not indicate such the large value as the calculated value described above. However, since a stress is generated in the glass substrate due to a difference in the amount of thermal expansion among strip parts and birefringence index is degraded, even though the value is a calculation value, the distribution of the amount of thermal expansion is preferably small and it is not preferably greater than 0.5 nm as described above.

In addition, in Examples 3, 5, 7 to 11, and 14 to 18, the fluorine concentration distribution in the pattern forming region is less than or equal to 0.82 mass %, and thus the transmittance distribution at a wavelength of 193 nm in the pattern forming region is sufficiently small as less than or equal to 0.1% and the absorption coefficient k₁₆₃ at a wavelength of 163 nm in the pattern forming region satisfies the relationship of the equation (1). Therefore, the transmittance at a wavelength of 193 nm is sufficiently large as greater than or equal to 90.75%.

Examples 16 and 17 are examples in which the influence of the average fictive temperature is evaluated on the basis of Example 3. Example 18 is an example in which the influence of the average fictive temperature is evaluated on the basis of Example 14.

In Example 16, the average fictive temperature is 1,110° C. which is 100° C. higher than that of Example 3. In comparison of Example 16 with Example 3, in Example 16, the amount of thermal expansion due to an increase of 0.1° C. in the temperature region of from 20° C. to 27° C. in strip part is 0.38 nm smaller than that of Example 3. In Example 17, the average fictive temperature is 980° C. which is 30° C. lower than that of Example 3. As with Example 16 and Example 3 described above, in comparison of Example 17 with Example 3, in Example 3, the amount of thermal expansion is 0.09 nm smaller than that of Example 17. In Example 18, the average fictive temperature is 1,110° C. which is 100° C. higher than that of Example 14. As with Example 16 and Example 3 described above, in comparison of Example 18 with Example 14, in Example 18, the amount of thermal expansion is 0.38 nm smaller than that of Example 14. From Examples 3, 14, and 16 to 18, it is found that the amount of thermal expansion further decreases as the average fictive temperature becomes higher.

Although the present invention has been described in detail and by reference to the specific embodiments, it is apparent to one skilled in the art that various modifications or changes can be made without departing the spirit and scope of the present invention.

This application is based on Japanese Patent Applications No. 2014-160202 filed on Aug. 6, 2014 and No. 2015-153162 filed on Aug. 3, 2015, the disclosures of which are incorporated herein by reference.

What is claimed is:

1. A glass substrate for optical lithography comprising a fluorine-containing synthetic quartz glass,
wherein the glass substrate has a pattern forming region, and
when the pattern forming region is divided into a plural parts each having a strip shape along a long side direction of the pattern forming region such that the number of divisions is greater than or equal to 3, each said part has an average fluorine concentration of greater than or equal to 1 mass % and a distribution of the average fluorine concentration among the parts is less than or equal to 0.45 mass %.

2. The glass substrate for optical lithography according to claim 1,
wherein the glass substrate has a fluorine concentration distribution being less than or equal to 0.82 mass % in the pattern forming region.

3. The glass substrate for optical lithography according to claim 1,
wherein the glass substrate has an absorption coefficient k₁₆₃ (1/cm) at a wavelength of 163 nm in the pattern forming region, satisfying the following equation (1):
$${k}_{163} ( 1 / cm ) ≦ a ln [ \frac{1}{1 - Δ T} ] \qquad ( 1 )$$
in the equation (1), a is 9.74×10⁴, and ΔT is denoted by the following equation (2):
$$Δ T = \frac{2 {bW}_{F} ( - 1 + {n}_{0} ( {n}_{0} - {bW}_{F} ) )}{( 1 + {n}_{0}^{2} ) ( 1 + {( {n}_{0} - {bW}_{F} )}^{2} )} \qquad ( 2 )$$
in the equation (2), n₀ is 1.561, b is 5.04×10⁻³, and W_{F} is a fluorine concentration (mass %) in the pattern forming region.

4. The glass substrate for optical lithography according to claim 1,
wherein each part has an average fictive temperature being higher than or equal to 1,000° C.
